(19) United States
(12) Patent Application Publication
(10) Pub. No.: US 2025/0079418 A1
(43) Pub. Date: Mar. 6, 2025

(54) SEMICONDUCTOR DEVICE

(71) Applicant: SUMITOMO ELECTRIC DEVICE INNOVATIONS, INC., Yokohama-shi (JP)

(72) Inventor: Takuma MORI, Yokohama-shi (JP)

(73) Assignee: SUMITOMO ELECTRIC DEVICE INNOVATIONS, INC., Yokohama-shi (JP)

(21) Appl. No.: 18/813,817

(22) Filed: Aug. 23, 2024

(30) Foreign Application Priority Data
Aug. 28, 2023 (JP) 2023-138189

(51) Int. Cl. H01L 25/16; H01L 23/00; H01L 23/31; H01L 23/498; H01L 23/66

(52) U.S. Cl. CPC H01L 25/16; H01L 23/3107; H01L 23/49811; H01L 23/49838; H01L 23/66; H01L 24/46; H01L 24/48; H01L 2223/6611; H01L 2224/46; H01L 2224/48195; H01L 2224/48227; H01L 2924/19041

(57) ABSTRACT

A semiconductor device includes a base, one or a plurality of chips that include a semiconductor chip provided on the base, a first bonding wire connected to at least one of the one or the plurality of chips, a second bonding wire that extends in a direction intersecting with an extending direction of the first bonding wire when viewed from a thickness direction of the base, and a resin layer that is provided on the base and seals the one or the plurality of chips, the first bonding wire and the second bonding wire. The first bonding wire and the second bonding wire are not in contact with each other, and the first bonding wire is contactable with the second bonding wire when the first bonding wire is inclined toward the second bonding wire.

### CROSS REFERENCE TO RELATED APPLICATIONS

This application claims priority based on Japanese Patent Application No. 2023-138189 filed on Aug. 28, 2023, and the entire contents of the Japanese patent applications are incorporated herein by reference.

### FIELD

A certain aspect of the embodiments is related to a semiconductor device.

### BACKGROUND

It is known to mount a chip on a conductive base and connect bonding wires to the chip (for example, Patent Document 1: Japanese Laid-Open Patent Application No. 2018-113284).

### SUMMARY

A semiconductor device according to the present disclosure includes: a base; one or a plurality of chips that include a semiconductor chip provided on the base; a first bonding wire connected to at least one of the one or the plurality of chips; a second bonding wire that extends in a direction intersecting with an extending direction of the first bonding wire when viewed from a thickness direction of the base; and a resin layer that is provided on the base and seals the one or the plurality of chips, the first bonding wire and the second bonding wire; wherein the first bonding wire and the second bonding wire are not in contact with each other, and the first bonding wire is contactable with the second bonding wire when the first bonding wire is inclined toward the second bonding wire.

### BRIEF DESCRIPTION OF DRAWINGS

FIG. 1 is a plan view of a semiconductor device according to a first embodiment.

FIG. 2 is a cross-sectional view taken along a line A-A in FIG. 1.

FIG. 3 is a cross-sectional view taken along a line B-B in FIG. 1.

FIG. 4 is a circuit diagram of one set in the semiconductor device according to the first embodiment.

FIG. 5 is a flowchart illustrating a method of manufacturing the semiconductor device according to the first embodiment.

FIG. 6 is a cross-sectional view of a semiconductor device according to a first comparative example.

FIG. 7 is a cross-sectional view taken along a line A-A of FIG. 6.

FIG. 8 is a cross-sectional view of the semiconductor device according to the first embodiment.

FIG. 9 is a side view of bonding wires viewed from a Y direction according to the first embodiment.

FIG. 10 is a side view of the bonding wires viewed from an X direction according to the first embodiment.

FIG. 11 is a plan view of the bonding wires according to the first embodiment.

FIG. 12 is a plan view of the bonding wires according to the first embodiment.

FIG. 13 is a plan view of a semiconductor device according to a second embodiment.

FIG. 14 is a cross-sectional view taken along a line A-A in FIG. 13.

FIG. 15 is a circuit diagram of one set in the semiconductor device according to the second embodiment.

FIG. 16 is a plan view of a semiconductor device according to a third embodiment.

### DETAILED DESCRIPTION OF EMBODIMENTS

When the chip and the bonding wires are resin-sealed, the characteristics of the bonding wires are changed if the shapes of the bonding wires are changed. If an X-ray transmission inspection apparatus is used to inspect the shapes of the bonding wires in the sealing resin, the number of manufacturing steps increases.

The present disclosure has been made in view of the above problems, and an object thereof is to enable inspection of the bonding wires.

### Details of Embodiments of the Present Disclosure

First, the contents of the embodiments of this disclosure are listed and explained.
(1) A semiconductor device according to the present disclosure includes: a base; one or a plurality of chips that include a semiconductor chip provided on the base; a first bonding wire connected to at least one of the one or the plurality of chips; a second bonding wire that extends in a direction intersecting with an extending direction of the first bonding wire when viewed from a thickness direction of the base; and a resin layer that is provided on the base and seals the one or the plurality of chips, the first bonding wire and the second bonding wire; wherein the first bonding wire and the second bonding wire are not in contact with each other, and the first bonding wire is contactable with the second bonding wire when the first bonding wire is inclined toward the second bonding wire. Thereby, the inclination of the first bonding wire can be detected.
(2) In the above (1), the semiconductor device further may include: a first terminal connected to the first bonding wire in a DC manner; and a second terminal connected to the second bonding wire in the DC manner. The base, and the first terminal and the second terminal may not be connected to each other in the DC manner. Thereby, the inclination of the first bonding wire can be detected.
(3) In the above (1) or (2), the first bonding wire may be contactable with the second bonding wire when the first bonding wire is inclined by 45° or more from the thickness direction of the base toward the second bonding wire. Thereby, the inclination of the first bonding wire can be detected.
(4) In any one of the above (1) to (3), when the second bonding wire is divided into three portions as viewed from the thickness direction of the base, a point of the second bonding wire farthest from the base may be located at a portion closest to the first bonding wire in three divided portions of the second bonding wire. Thereby, the inclination of the first bonding wire can be detected.
(5) In any one of the above (1) to (4), an angle between a direction of an extending direction of the first bonding wire and a direction of an extending direction of the second bonding wire may be 45° or more when viewed from the thickness direction of the base. Thereby, the influence of the second bonding wire on the characteristic of the first bonding wire can be reduced.
(6) In any one of the above (1) to (5), the semiconductor device further may include a plurality of second bonding wires. At least two of the plurality of second bonding wires may be provided with the first bonding wire interposed therebetween. Thereby, the inclination of the first bonding wire in any direction can be detected.
(7) In any one of the above (1) to (6), both ends of the second bonding wire may be bonded to the base. This allows the second bonding wire to be set at a reference potential.
(8) In any one of the above (1) to (7), both ends of the first bonding wire may be bonded to one chip in the one or the plurality of chips, and a first end in both ends of the second bonding wire, which is closer to the first bonding wire, may be bonded to the one chip. Thereby, the inclination of the first bonding wire bonded on the chip can be detected.
(9) In any one of the above (1) to (8), the first bonding wire may be the longest in bonding wires for transmitting signals in the semiconductor device. Thereby, the inclination of the first bonding wire which is likely to be inclined can be detected.
(10) In any one of the above (1) to (9), the first bonding wire may transmit a high frequency signal. Thereby, a change in the high frequency characteristic of the first bonding wire can be detected.
(11) In the above (10), the one or the plurality of chips may include the semiconductor chip and a passive element chip, and the first bonding wire may electrically connect the semiconductor chip and the passive element chip. Thereby, the inclination of the first bonding wire, which is difficult to adjust, can be detected.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

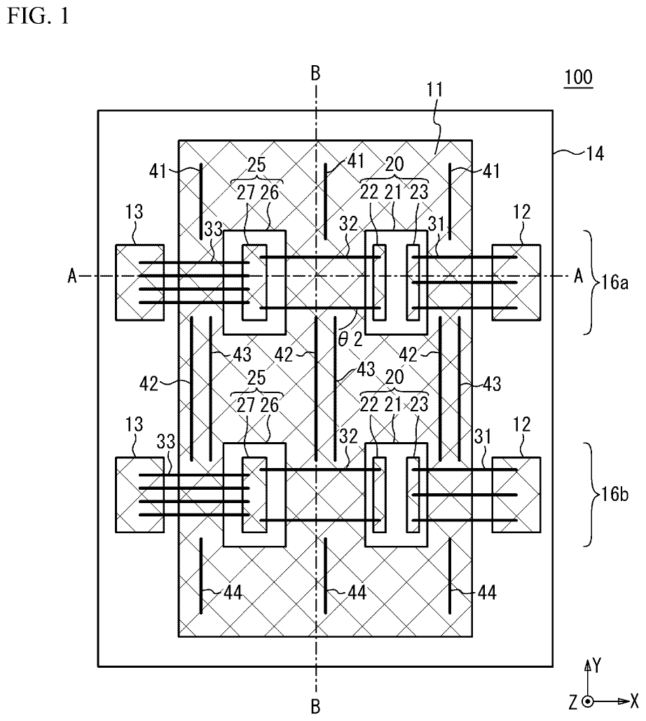

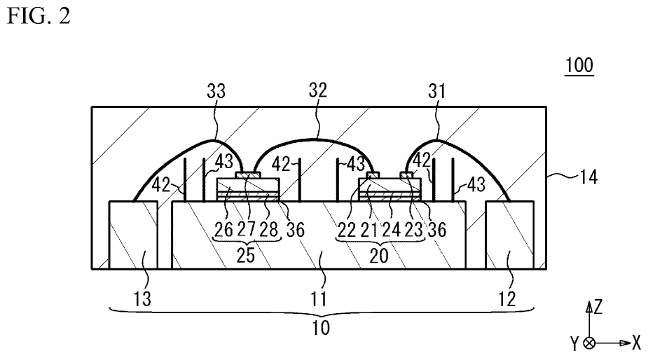

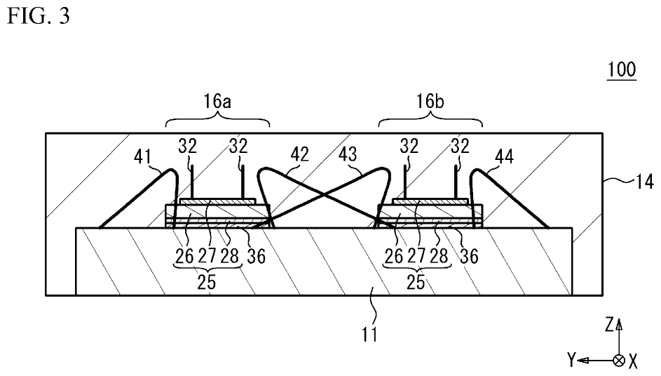

FIG. 1 is a plan view of a semiconductor device according to a first embodiment. FIG. 2 is a cross-sectional view taken along a line A-A in FIG. 1. FIG. 3 is a cross-sectional view taken along a line B-B in FIG. 1. In FIGS. 2 and 3, bonding wires 31 to 33 and 41 to 44 in the vicinity of the cross-sectional line are also illustrated. A thickness direction of a base 11 is defined as a Z direction, an extending direction of a straight line connecting terminals 12 and 13 is defined as an X direction, and a direction orthogonal to the X direction and the Z direction is defined as a Y direction.

As illustrated in FIGS. 1 to 3, a semiconductor device 100 of the first embodiment has a structure in which a semiconductor chip 20 and a passive element chip 25 mounted on the base 11 of a conductive lead frame 10 are sealed with a resin layer 14. The lead frame 10 has the base 11 and the terminals 12 and 13. The base 11 and the terminals 12 and 13 are not in contact with each other. The base 11 is a die pad, and the terminals 12 and 13 are leads. Connecting bars for connecting the base 11, the terminal 12 and the terminal 13 before cutting are not illustrated. The lower surfaces of the base 11 and the terminals 12 and 13 are exposed from the lower surface of the resin layer 14.

The terminal 12, the semiconductor chip 20, the passive element chip 25 and the terminal 13 are arranged in order in a −direction in the X direction. Two sets 16a and 16b each including the terminal 12, the semiconductor chip 20, the passive element chip 25, and the terminal 13 are provided, and the two sets 16a and 16b are arranged in the Y direction. The number of sets 16a and 16b may be one or three or more.

The semiconductor chip 20 and the passive element chip 25 are mounted on the base 11. The semiconductor chip 20 includes a substrate 21 and electrodes 22 to 24. The substrate 21 is, for example, a semiconductor substrate. The electrodes 22 and 23 are provided on the upper surface of the substrate 21. The electrode 24 is provided on the lower surface of the substrate 21. The passive element chip 25 includes a substrate 26 and electrodes 27 and 28. The substrate 26 is, for example, a dielectric substrate. The electrode 27 is provided on the upper surface of the substrate 26, and the electrode 28 is provided on the lower surface of the substrate 26. A bonding layer 36 having conductivity bonds the base 11 to the electrodes 24 and 28. The electrodes 24 and 28 are electrically connected to and shorted to the base 11. The bonding wires 31 electrically connect the terminal 12 to the electrode 23. The bonding wires 32 electrically connect the electrode 22 to the electrode 27. The bonding wires 33 electrically connects the electrode 27 to the terminal 13.

The bonding wires 41 to 44 are provided on the base 11. The bonding wires 41 are provided adjacent to the bonding wires 31 to 33 and between the bonding wires 31 to 33 of the set 16a and a side of the base 11 located in the +direction in the Y direction. The bonding wires 42 are provided adjacent to the bonding wires 31 to 33 of the set 16a and between the bonding wires 31 to 33 of the set 16a and the set 16b. The bonding wires 43 are provided adjacent to the bonding wires 31 to 33 of the set 16b and between the bonding wires 31 to 33 of the set 16b and the set 16a. The bonding wires 44 are provided adjacent to the bonding wires 31 to 33 and between the bonding wires 31 to 33 of the set 16b and a side of the base 11 located in the −direction in the Y direction.

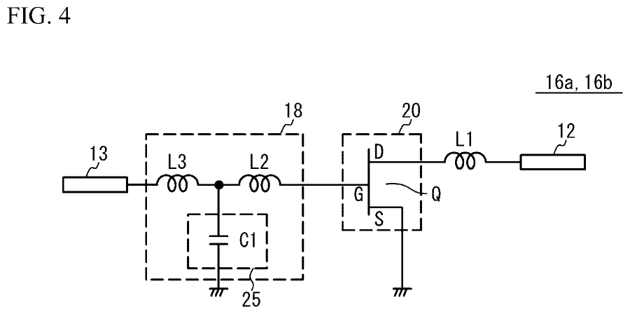

FIG. 4 is a circuit diagram of one set in the semiconductor device according to the first embodiment. As illustrated in FIG. 4, each of the sets 16a and 16b includes the terminals 12 and 13, a transistor Q, inductors L1 to L3, and a capacitor C1. The transistor Q is, for example, an FET (Field Effect Transistor), and has a source S, a gate G, and a drain D. The inductors L2 and L5 are connected in series between the terminal 13 and the gate G. The capacitor C1 is shunt-connected to a node between the inductors L2 and L3. The source S is grounded. The inductor L1 is connected between the drain D and the terminal 12. The inductors L2 and L3 and the capacitor C1 are an LCL type circuit and form a matching circuit 18. The matching circuit 18 matches an impedance when the matching circuit 18 is seen from the terminal 13 with an impedance when the transistor Q is seen from the matching circuit 18.

The transistor Q is provided in the semiconductor chip 20. The source S, the gate G and the drain D correspond to the electrodes 24, 22 and 23, respectively. The electrode 22 is an input electrode to which a high frequency signal is input, and the electrode 23 is an output electrode to which a high frequency signal is output. The capacitor C1 is provided in the passive element chip 25 and corresponds to the substrate 26 and the electrodes 27 and 28 sandwiching the substrate 26. The inductors L1, L2 and L3 correspond to the bonding wires 31, 32 and 33, respectively.

The high frequency signal input to the terminal 13 passes through the matching circuit 18 and is input to the gate G. The high frequency signal amplified by the transistor Q passes through the inductor L1 from the drain D and is output to the terminal 12. The inductor L1 may form a part of a matching circuit. When the semiconductor device 100 is used as an amplifier circuit for a base station of mobile communication, the frequency of the high frequency signal is, for example, 0.5 GHz to 10 GHz. The frequency of the high frequency signal may be 10 GHz or more.

The transistor Q is, for example, a GaN HEMT (Gallium Nitride High Electron Mobility Transistor) or an LDMOS (Laterally Diffused Metal Oxide Semiconductor). When the transistor Q is the GaN HEMT, the substrate 21 is, for example, a silicon carbide substrate or a gallium nitride substrate. The electrodes 22 to 24 are metal layers, such as gold layers.

When the passive element chip 25 has the capacitor C1, the substrate 26 is, for example, a dielectric substrate, and examples thereof include an alumina (aluminum oxide) substrate, a high-dielectric ceramic substrate having a larger relative dielectric constant than that of the alumina substrate, a silicon substrate, or a gallium arsenide substrate. The electrodes 27 and 28 are metal layers such as gold layers.

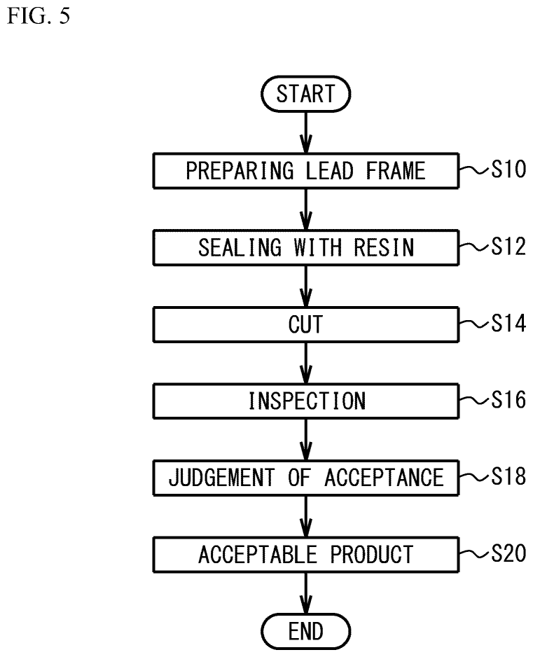

FIG. 5 is a flowchart illustrating a method of manufacturing the semiconductor device according to the first embodiment. As illustrated in FIG. 5, a frame in which the plurality of lead frames 10 are connected by the connecting bars is prepared (step S10). In step S10, the semiconductor chip 20 and the passive element chip 25 are mounted on the base 11, and the bonding wires 31 to 33 are bonded to the semiconductor chip 20 or the passive element chip 25 and the bonding wires 41 to 44 are bonded to the base 11.

Next, the frame is sealed with resin (step S12). In step S12, the frame is placed in a mold, and a resin to be the resin layer 14 is injected into the mold by a transfer molding method. Next, the resin layer 14 and the frame are cut (step S14). Thus, the semiconductor device 100 illustrated in FIGS. 1 to 3 is completed.

Next, the semiconductor device 100 is electrically inspected (step S16). In step S16, for example, the electrical short circuit between the terminal 12 and the base 11 and the electrical short circuit between the terminal 13 and the base 11 are inspected using a DC measuring device. Next, the semiconductor device 100 is judged to be acceptable or unacceptable based on the inspection result of the step S16 (step S18). In step S18, for example, if the terminal 12 and the base 11 are electrically short-circuited or the terminal 13 and the base 11 are electrically short-circuited, the semiconductor device 100 is judged to be unacceptable, and if the terminal 12 and the base 11 are not electrically short-circuited and the terminal 13 and the base 11 are not electrically short-circuited, the semiconductor device 100 is judged to be acceptable.

Next, the semiconductor device 100 judged to be acceptable in the step S18 is decided as an acceptable product (step S20). If the semiconductor device 100 is decided as the acceptable product in step S20, the semiconductor device 100 is stamped, for example.

### First Comparative Example

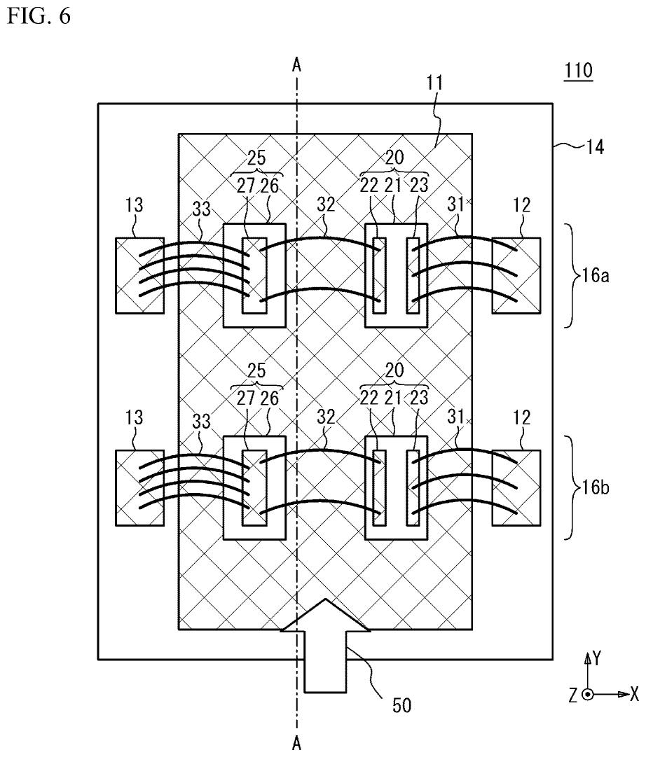

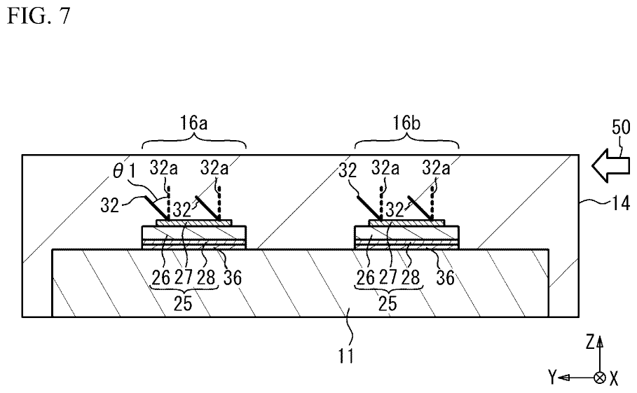

FIG. 6 is a cross-sectional view of a semiconductor device according to a first comparative example. FIG. 7 is a cross-sectional view taken along a line A-A in FIG. 6. As illustrated in FIGS. 6 and 7, a semiconductor device 110 of the first comparative example is not provided with the bonding wires 41 to 44. The resin layer 14 is formed by, for example, the transfer molding method. In step S12, the plurality of lead frames include lead frames into which a resin is injected from the −direction in the Y direction as indicated by an arrow 50 in FIGS. 6 and 7. In the lead frame 10, the bonding wires 31 to 33 are inclined by the flow of the resin. If the resin layer 14 is provided by, for example, a potting method other than the transfer molding method, the bonding wires 31 to 33 may be inclined when the resin flows.

In FIG. 7, bonding wires 32a illustrate the state of the bonding wires 32 before the resin is injected, and the bonding wires 32 illustrate the state thereof after the resin is injected. The bonding wires 32 are inclined at an angle θ1. When the bonding wires 32 are inclined, the high frequency characteristics of the bonding wires 32 are changed. If the angle θ1 is too large, the bonding wires 32 may short-circuit with other components. Therefore, when the inclination of the bonding wire 32 is to be inspected, an expensive apparatus such as an X-ray transmission inspection apparatus is used.

### Description of First Embodiment

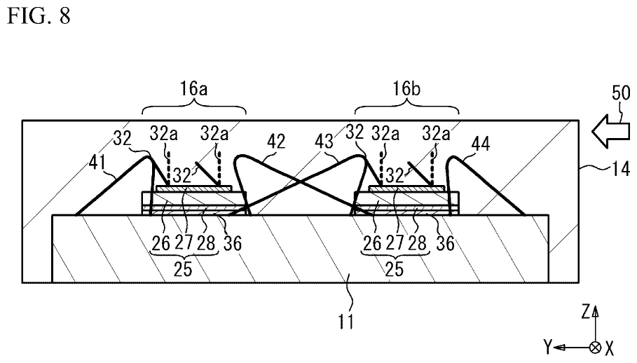

FIG. 8 is a cross-sectional view of a semiconductor device according to the first embodiment. As illustrated in FIG. 8, when the bonding wires 32 are inclined, the bonding wires 32 comes into contact with the bonding wires 41 and 43. Thereby, the terminal 13 and the base 11 are electrically short-circuited. In step S16 of FIG. 5, therefore, the electrical short-circuit between the terminal 13 and the base 11 is inspected. In step S18, if the terminal 13 and the base 11 are electrically short-circuited, the semiconductor device is judged to be unacceptable. In this way, the inclination of the bonding wires 32 can be inspected.

According to the first embodiment, as illustrated in FIGS. 1 to 3, the terminal 12 (first terminal) is connected to the bonding wires 31 (first bonding wire) in a direct current (DC) manner, and the terminal 13 (first terminal) is connected to the bonding wires 32 and 33 (first bonding wire) in the DC manner. The base 11 (second terminal) is connected to the bonding wires 41 to 44 (second bonding wires) in the DC manner. The base 11 and the terminals 12 and 13 are not connected in the DC manner. Thus, by detecting the DC short-circuit between the terminals 12 and 13 and the base 11 in step S16, the inclination of the bonding wires 31 to 33 can be detected as indicated by step S18.

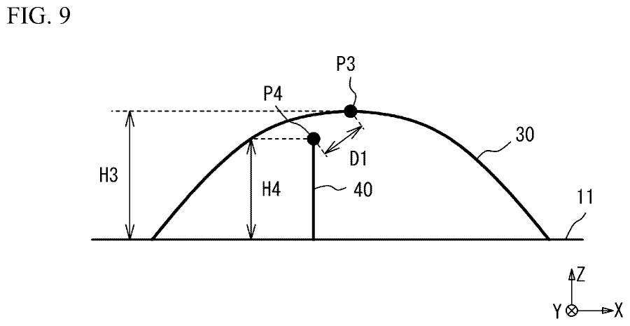

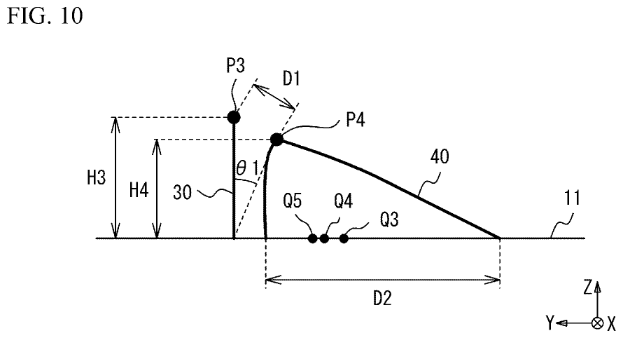

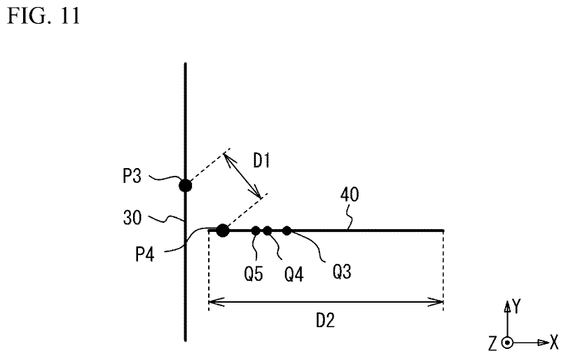

FIG. 9 is a side view of bonding wires viewed from the Y direction according to the first embodiment. FIG. 10 is a side view of the bonding wires viewed from the X direction according to the first embodiment. FIG. 11 is a plan view of the bonding wires according to the first embodiment. In FIGS. 9 to 11, a bonding wire 30 corresponds to the bonding wires 31 to 33, and a bonding wire 40 corresponds to the bonding wires 41 to 44. The vertices of the bonding wires 30 and 40 are P3 and P4, respectively. The bonding wires 30 and 40 have heights H3 and H4, respectively. The vertices P3 and P4 of the bonding wires 30 and 40 are the points farthest from the base 11 of the bonding wires 30 and 40 as subjects. The heights of the bonding wires 30 and 40 are heights in the Z direction between lower ends (closer to the base 11) of both ends of the bonding wire 30 and 40 as subjects and the vertices P3 and P4.

As illustrated in FIG. 10, the bonding wires 30 and 40 are not in contact with each other, and the bonding wire 30 is contactable with the bonding wire 40 when the bonding wire 30 is inclined toward the bonding wire 40. Thereby, the inclination of the bonding wire 30 can be detected by detecting the electrical contact between the bonding wires 30 and 40.

When the bonding wire 30 is tilted by an angle θ1 from the Z direction toward the bonding wire 40, the bonding wire 30 is contactable with the bonding wire 40. The angle θ1 may be, for example, 45° or less, 30° or less, or 15° or less. When the angle θ1 increases, the high frequency characteristic of the bonding wire 30 are greatly changed. Therefore, by reducing the angle θ1, the change in the high frequency characteristic of the bonding wire 30 can be detected with high accuracy. If the angle θ1 is too small, the bonding wires 30 and 40 come into contact with each other even if the inclination of the bonding wires 30 is within a manufacturing error. From this viewpoint, the angle θ1 can be set to 5° or more.

A shortest distance between the bonding wires 30 and 40 is defined as a distance D1. In FIGS. 9 to 11, a distance between the vertices P3 and P4 is assumed to be the shortest distance D1. By making the distance D1 smaller than a height H3, the bonding wires 30 and 40 are more likely to come into contact with each other when the bonding wire 30 is inclined. The distance D1 may be equal to or less than one times the height H3, three quarters of the height H3, or one half of the height H3.

The bonding wire 40 is made asymmetric so that the bonding wire 30 is contactable with the bonding wire 40 when the bonding wire 30 is inclined. When the length of the bonding wire 40 viewed from the Z direction is defined as D2, a position of ⅓×D2 away from an end of the bonding wire 40 closer to the bonding wire 30 in both ends of the bonding wire 40 viewed from the Z direction is defined as Q3, a position of ¼×D2 away from the end of the bonding wire 40 closer to the bonding wire 30 is defined as Q4, and a position of ⅕×D2 is away from the end of the bonding wire 40 closer to the bonding wire 30 is defined as Q5. The apex P4 is located closer to the bonding wire 30 than the position Q3 when viewed from the Z direction. That is, when the bonding wire 40 is divided into three portions as viewed in the Z direction, the vertex P4 is located at a portion closest to the bonding wire 30 in the three divided portions. The vertex P4 may be located closer to the bonding wire 30 than the position Q4, and may be located closer to the bonding wire 30 than the position Q5. In this way, the bonding wire 40 is made asymmetric, whereby the shortest distance D1 can be reduced.

If a height H4 is too low, the bonding wire 30 is not in contact with the bonding wire 40 even if the bonding wire 30 is inclined. From this viewpoint, the height H4 can be 0.5 times or more the height H3, or 0.8 times or more the height H3.

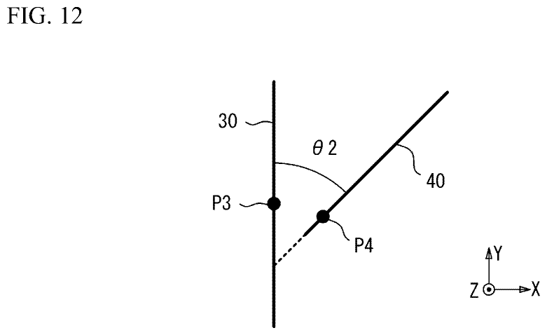

FIG. 12 is a plan view of the bonding wires according to the first embodiment. When viewed from the Z direction, an angle between an extending direction of the bonding wire 30 and an extending direction of the bonding wire 40 is defined as θ2. The angle θ2 need not be 90°. The extending direction of the bonding wire 30 and the extending direction of the bonding wire 40 may intersect with each other. From the viewpoint of reducing the influence of the bonding wire 40 on the high frequency characteristic of the bonding wire 30, the angle θ2 can be set to 45° or more, 60° or more, or 80° or more.

As illustrated in FIG. 8, at least two bonding wires 41 and 42 are provided with the bonding wire 32 interposed therebetween. Thereby, the inclination of the bonding wire 32 can be detected even if the bonding wire 32 is inclined in either the +direction or the −direction in the Y direction.

The both ends of each of the bonding wires 41 to 44 are bonded to the base

11. This allows the bonding wires 41 to 44 to be set to the reference potential. Thus, by detecting an electrical short-circuit between the base 11 and the terminal 12 or 13, the inclination of the bonding wires 31 to 33 can be detected.

When the bonding wires 31 to 33 transmit high frequency signals, the high frequency characteristics of the bonding wires 31 to 33 are changed when the bonding wires 31 to 33 are inclined. Therefore, by providing the bonding wires 41 to 44 adjacent to the bonding wires 31 to 33, it is possible to detect changes in the high frequency characteristics of the bonding wires 31 to 33.

If the high frequency characteristic of the bonding wire 32 electrically connecting the semiconductor chip 20 and the passive element chip 25 changes, the characteristic of the matching circuit 18 cannot be adjusted from the outside of the semiconductor device 100. Therefore, it is important to detect the inclination of the bonding wire 32. Therefore, the bonding wires 41 and 42 adjacent to the bonding wire 32 are provided.

### Second Embodiment

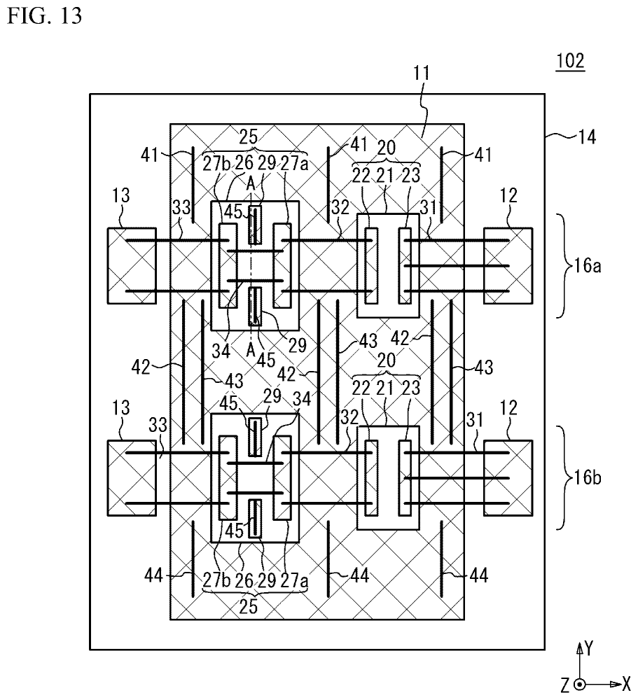

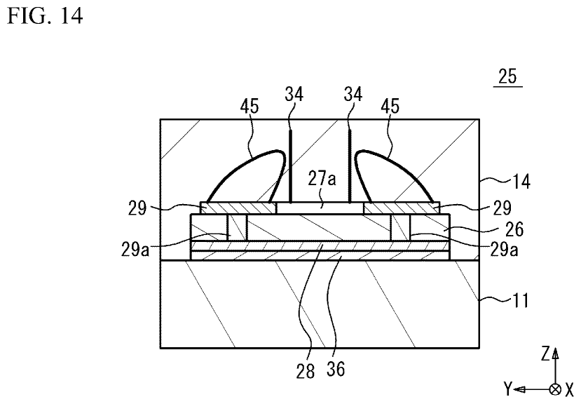

FIG. 13 is a plan view of a semiconductor device according to a second embodiment. FIG. 14 is a cross-sectional view taken along a line A-A in FIG. 13. As illustrated in FIGS. 13 and 14, in a semiconductor device 102 of the second embodiment, electrodes 27a and 27b are provided on the upper surface of the passive element chip 25. Bonding wires 34 electrically connect the electrodes 27a and 27b. The bonding wire 32 electrically connects the electrodes 22 and 27a. The bonding wire 33 electrically connects the electrode 27b and the terminal 13. Electrodes 29 are provided on the substrate 26 so as to interpose the bonding wires 34 therebetween in the Y direction. Bonding wires 45 are bonded to the electrodes 29. Each of vias 29a penetrates the substrate 26, and electrically connects and short-circuits the electrodes 28 and 29. Thereby, the bonding wire 45 has the same potential as the potential of the base 11.

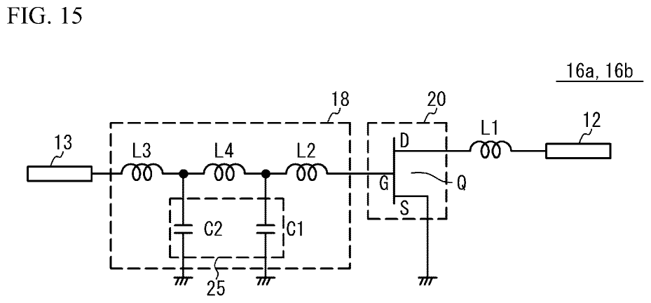

FIG. 15 is a circuit diagram of one set in the semiconductor device according to the second embodiment. As illustrated in FIG. 15, an inductor L4 is connected in series between the inductors L2 and L3. The capacitor C1 is shunt-connected between the inductors L2 and L4. A capacitor C2 is shunt-connected between the inductors L4 and L3. The inductors L2 to L4 and the capacitors C1 and C2 form the matching circuit 18. The capacitors C1 and C2 are provided in the passive element chip 25. The inductor L4 corresponds to the bonding wire 34 that electrically connects the electrodes 27a and 27b. The capacitor C1 corresponds to the substrate 26 and the electrodes 27a and 28 sandwiching the substrate 26. The capacitor C2 corresponds to the substrate 26 and the electrodes 27b and 28 sandwiching the substrate 26. The other configurations of the second embodiment are the same as those of the first embodiment, and the description thereof is omitted.

In the case where both ends of the bonding wire 34 are bonded on one passive element chip 25 as in the second embodiment, it is difficult to provide the bonding wire adjacent to the bonding wire 34 on the base 11. Therefore, a first end in the both ends of the bonding wire 45, which is closer to the bonding wire 34, is bonded to the passive element chip 25. Thus, the inclination of the bonding wire 34 can be detected.

### Third Embodiment

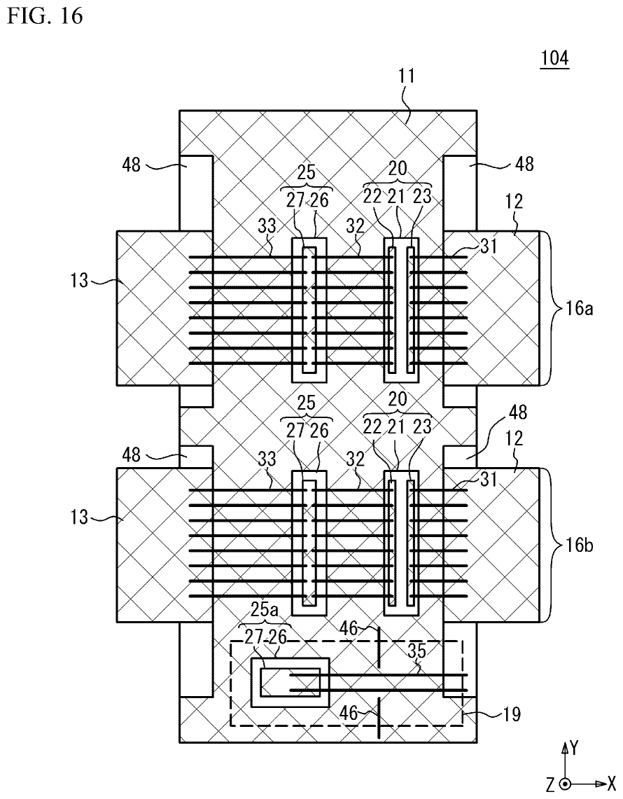

FIG. 16 is a plan view of a semiconductor device according to a third embodiment. As illustrated in FIG. 16, in a semiconductor device 104 of the third embodiment, the semiconductor chips 20 and the passive element chips 25 are mounted on the base 11. A conductor layer 48 is provided on the base 11 via an insulating layer. The terminals 12 and 13 are provided on the conductor layer 48 in electrical contact therewith. The bonding wires 31 to 33 are connected in the same manner as in the first embodiment. A passive element chip 25a is provided on the base 11. The passive element chip 25a includes the substrate 26 and the electrode 27. The electrode 27 and the conductive layer 48 are electrically connected by bonding wires 35. Bonding wires 46 are provided on the base 11 so as to interpose the bonding wires 35 therebetween in the Y direction.

The bonding wires 35 and the passive element chip 25a form a VBW (Video Band Width) circuit 19. The VBW circuit 19 allows a signal having a frequency lower than the operating band in the high frequency signals flowing through the terminal 12 to pass to the ground and does not allow signals in the operating band to pass to the ground. Therefore, the passive element chip 25a has a large capacitance to pass a signal having a low frequency. The bonding wire 35 has a large inductance so as not to pass the high frequency signal in the operating band. Therefore, the bonding wire 35 becomes long, and is likely to be inclined when a resin is injected. Therefore, the bonding wires 46 are provided so as to interpose the bonding wires 35 therebetween in the Y direction, so that the inclination of the bonding wires 35 can be detected. The other configurations of the third embodiment are the same as those of the first embodiment, and the description thereof is omitted.

In the third embodiment, the bonding wire 35 is the longest of the bonding wires 31 to 33 and 35 for transmitting signals. In this case, the bonding wires 46 are provided adjacent to the bonding wirer 35. Thus, the inclination of the bonding wires 35 can be detected.

The shortest bonding wire 31 of the bonding wires 31 to 33 and 35 for transmitting signals is less likely to incline. Therefore, a bonding wire adjacent to the bonding wire 31 may not be provided. In this way, no corresponding bonding wire of the bonding wires 41 to 44 is provided adjacent to at least one of the bonding wires 31 to 33 for transmitting a signal other than the longest bonding wire 35. This allows the semiconductor device to be reduced in size.

Although the first to third embodiments have described the example in which the high frequency signals are transmitted to the bonding wires 31 to 35, signals other than the high frequency signals may be transmitted to the bonding wires 31 to 35, or a reference potential may be supplied thereto. When the bonding wires 31 to 35 transmit the high frequency signals, the high frequency signals of the bonding wires 31 to 35 are likely to change when the bonding wires 31 to 35 are inclined. Accordingly, the bonding wires 41 to 46 are provided adjacent to the bonding wires 31 to 35 through which the high frequency signals flow.

The embodiments disclosed here should be considered as illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a base;
one or a plurality of chips that include a semiconductor chip provided on the base;
a first bonding wire connected to at least one of the one or the plurality of chips;
a second bonding wire that extends in a direction intersecting with an extending direction of the first bonding wire when viewed from a thickness direction of the base; and
a resin layer that is provided on the base and seals the one or the plurality of chips, the first bonding wire and the second bonding wire;
wherein the first bonding wire and the second bonding wire are not in contact with each other, and the first bonding wire is contactable with the second bonding wire when the first bonding wire is inclined toward the second bonding wire.

2. The semiconductor device according to claim 1, further comprising:
a first terminal connected to the first bonding wire in a DC manner; and
a second terminal connected to the second bonding wire in the DC manner;
wherein the base, and the first terminal and the second terminal are not connected to each other in the DC manner.

3. The semiconductor device according to claim 1, wherein
the first bonding wire is contactable with the second bonding wire when the first bonding wire is inclined by 45° or more from the thickness direction of the base toward the second bonding wire.

4. The semiconductor device according to claim 1, wherein
when the second bonding wire is divided into three portions as viewed from the thickness direction of the base, a point of the second bonding wire farthest from the base is located at a portion closest to the first bonding wire in three divided portions of the second bonding wire.

5. The semiconductor device according to claim 1, wherein
an angle between a direction of an extending direction of the first bonding wire and a direction of an extending direction of the second bonding wire is 45° or more when viewed from the thickness direction of the base.

6. The semiconductor device according to claim 1, further comprising:
a plurality of second bonding wires;
wherein at least two of the plurality of second bonding wires are provided with the first bonding wire interposed therebetween.

7. The semiconductor device according to claim 1, wherein
both ends of the second bonding wire are bonded to the base.

8. The semiconductor device according to claim 1, wherein
both ends of the first bonding wire are bonded to one chip in the one or the plurality of chips, and
a first end in both ends of the second bonding wire, which is closer to the first bonding wire, is bonded to the one chip.

9. The semiconductor device according to claim 1, wherein
the first bonding wire is the longest in bonding wires for transmitting signals in the semiconductor device.

10. The semiconductor device according to claim 1, wherein
the first bonding wire transmits a high frequency signal.

11. The semiconductor device according to claim 10, wherein
the one or the plurality of chips include the semiconductor chip and a passive element chip, and
the first bonding wire electrically connects the semiconductor chip and the passive element chip.
